(19) United States
(12) Patent Application Publication
(10) Pub. No.: US 2026/0337808 A1
(43) Pub. Date: Oct. 29, 2026

(54) SAFE SEAL RETAINER SHIELD TO REDUCE CURRENT CROWDING NEAR SEAL FLAT COVERING NOTCH

(71) Applicant: Applied Materials, Inc., Santa Clara, CA (US)

(72) Inventors: Paul R. McHugh, Kalispell, MT (US); Gregory J. Wilson, Kalispell, MT (US); Josiah E. Bumgarner, Kalispell, MT (US)

(73) Assignee: Applied Materials, Inc., Santa Clara, CA (US)

(21) Appl. No.: 19/650,030

(22) Filed: Apr. 16, 2026

Related U.S. Application Data
(60) Provisional application No. 63/796,040, filed on Apr. 28, 2025.

(51) Int. Cl. C25D 17/00; C25D 17/06; H10P 72/00

(52) U.S. Cl. CPC C25D 17/004; C25D 17/005; C25D 17/06; H10P 72/0404

(57) ABSTRACT

electroplating systems may include a vessel that holds an electrolyte. The systems may include a substrate carrier head that may include a retainer shield. The retainer shield may include an annular seal insert that forms an outermost surface of the retainer shield. A distal end of the seal insert may include arcuate first and second regions. The first arcuate region may form at least 320 degrees of a circumference of the seal insert. The second arcuate region may form no greater than 40 degrees of the circumference. The first arcuate region may include a protrusion distance that is uniform along the first arcuate region. The second arcuate region may include a greater protrusion distance. The substrate carrier head may be moveable between a loading position and a plating position. The systems may include an anode disposed below the retainer shield when the carrier head is in the plating position.

### CROSS-REFERENCE TO RELATED APPLICATIONS

This application claims benefit of U.S. Provisional Patent Application No. 63/796,040, entitled, “SAFE SEAL RETAINER SHIELD TO REDUCE CURRENT CROWDING NEAR SEAL FLAT COVERING NOTCH,” filed Apr. 28, 2025, the contents of which are hereby incorporated by reference in their entirety.

### TECHNICAL FIELD

The present technology relates to the production of three-dimensional objects having improved surface characteristics. The present technology relates to objects useful in electroplating systems, such as system seals that may be used to support a substrate during electroplating operations.

### BACKGROUND OF THE INVENTION

Integrated circuits are made possible by processes which produce intricately patterned material layers on substrate surfaces. After formation, etching, and other processing on a substrate, metal or other conductive materials are often deposited or formed to provide the electrical connections between components. Because this metallization may be performed after many manufacturing operations, problems caused during the metallization may create expensive waste substrates or wafers.

During formation of metal materials on a wafer or substrate, a wafer may be submerged within a plating bath followed by metal formation on the wafer. The wafer may be held in place on an apparatus that submerges the wafer in a plating bath of electrolyte. The apparatus holding the wafer may include electrically conductive components contacting the wafer, allowing the wafer to operate as a cathode in the plating operation. Because the apparatus and electrical contacts may similarly be submerged within the plating bath, the apparatus may include a seal or multiple components operating as a seal to limit or prevent the electrolyte from contacting internal conductive components. Wafers often include a notch or flat region formed in a peripheral edge of the wafer, which may provide a gripping location for various tools and/or serve as a reference point for indicating that alignment of a crystalline structure of the wafer. However, due to this notch or flat region there may be plating uniformity issues, as the current density at the notch or flat region may be different than at the rest of the arcuate edge of the wafer.

Thus, there is a need for improved systems and components that can be used to support a substrate during electroplating operations. These and other needs are addressed by the present technology.

### BRIEF SUMMARY OF THE INVENTION

Electroplating systems may include a vessel configured to hold an electrolyte. The systems may include a substrate carrier head that may include a seal assembly. The seal assembly may include an annular seal insert that forms an outermost surface of the seal assembly. A distal end of the annular seal insert may include a first arcuate region and a second arcuate region. The first arcuate region may form at least 320 degrees of a circumference of the annular seal insert. The second arcuate region may form no greater than 40 degrees of the circumference of the annular seal insert. The first arcuate region may include a first protrusion distance that is uniform along a length of the first arcuate region. The second arcuate region may include a second protrusion distance that is greater than the first protrusion distance. The substrate carrier head may be moveable between a loading position and a plating position in which the distal end of the annular seal insert is in contact with the electrolyte. The systems may include an anode disposed below the seal assembly when the substrate carrier head is in the plating position. In some embodiments, the vessel may include a field shaping unit. A top surface of the field shaping unit may form a closest portion of the vessel to the seal assembly when the substrate carrier head is in the plating position. Within the second arcuate region, the distal end of the annular seal insert may aper from the first protrusion distance at a first end of second arcuate region to the second protrusion distance at a center of the second arcuate region and to the first protrusion distance at a second end of the second arcuate region. The distal end of the annular seal insert may taper continuously from the center of the second arcuate region to each of the first end and the second end of the second arcuate region. A flow path from the anode to an inner region of the vessel disposed radially inward of the annular seal insert may be defined by the distal end of the annular seal insert and an upper surface of the vessel. A minimum depth of the flow path may be reduced by at least 1.5 mm at an angular location of the second protrusion distance relative to the minimum depth of the flow path at an angular location of the first protrusion distance. A minimum depth of the flow path may be reduced by at least 50% at an angular location of the second protrusion distance relative to the minimum depth of the flow path at an angular location of the first protrusion distance. The seal assembly may include a plurality of electrically conductive substrate contacts disposed within a central opening of the seal assembly. At least 10 degrees of the seal assembly in angular alignment with the second arcuate region may be devoid of the plurality of electrically conductive substrate contacts. An entirety of the seal assembly in angular alignment with the second arcuate region may be devoid of the plurality of electrically conductive substrate contacts.

Some embodiments of the present technology may encompass seal assemblies for an electroplating system. The shields may include an annular support ring having a proximal end and a distal end. The shields may include an annular busbar coupled with the distal end of the annular support ring. The shields may include a plurality of electrically conductive substrate contacts disposed between the annular busbar and the annular support ring. The plurality of electrically conductive substrate contacts may extend into a central opening of the annular support ring. The plurality of electrically conductive substrate contacts may be disposed about a circumference of the central opening. The shields may include a seal member disposed against an outer surface of the annular busbar. The shields may include an annular seal insert disposed against an outer surface of the seal member. A distal end of the annular seal insert may form a distal end of the seal assembly. The distal end of the annular seal insert may include a first arcuate region and a second arcuate region. The first arcuate region may form at least 320 degrees of a circumference of the annular seal insert. The second arcuate region may form no greater than 40 degrees of the circumference of the annular seal insert. The first arcuate region may include a first protrusion distance that is uniform along a length of the first arcuate region. The second arcuate region may include a second protrusion distance that is greater than the first protrusion distance.

In some embodiments, at least 10 degrees of the seal assembly in angular alignment with the second arcuate region may be devoid of the plurality of electrically conductive substrate contacts. Within the second arcuate region, the distal end of the annular seal insert may taper from the first protrusion distance at a first end of second arcuate region to the second protrusion distance at a center of the second arcuate region and to the first protrusion distance at a second end of the second arcuate region. Each boundary between the first arcuate region and the second arcuate region may include a stepped transition from the first protrusion distance to the second protrusion distance. The annular seal insert may include a curved transition from the distal end to an outer surface of the annular seal insert. The distal end may be planar from an inner edge of the annular seal insert to the curved transition. The annular seal insert may include a curved transition from the distal end to an outer surface of the annular seal insert. The distal end of the annular seal insert may protrude to the second protrusion distance within a medial region that is disposed between an inner edge of the annular seal insert and the curved transition.

Some embodiments of the present technology may encompass methods of electroplating a substrate. The methods may include positioning a substrate within an annular seal insert of a substrate carrier head such that a flat region of a peripheral edge is aligned with a second arcuate region of a distal end of the annular seal insert. The distal end of the annular seal insert may include a first arcuate region and the second arcuate region. The first arcuate region may form at least 320 degrees of a circumference of the annular seal insert. The second arcuate region may form no greater than 40 degrees of the circumference of the annular seal insert. The first arcuate region may include a first protrusion distance that is uniform along a length of the first arcuate region. The second arcuate region may include a second protrusion distance that is greater than the first protrusion distance. The methods may include moving the substrate carrier head into a plating position in which the substrate and the distal end of the annular seal insert are in contact within an electrolyte held within an electroplating vessel. The methods may include delivering a current to the electrolyte from an anode via a flow path defined between an upper surface of the electroplating vessel and the distal end of the annular seal insert.

In some embodiments, an angular size of the second arcuate region may match an angular size of the flat region. An angular size of the second arcuate region may be smaller than an angular size of the flat region. An angular size of the second arcuate region may be greater than an angular size of the flat region. The substrate carrier head may include a plurality of electrically conductive substrate contacts disposed within a central opening of the substrate carrier head. At least 10 degrees of substrate carrier head in angular alignment with the second arcuate region may be devoid of the plurality of electrically conductive substrate contacts.

Such technology may provide numerous benefits over conventional systems and techniques. For example, the processes and systems may significantly improve the uniformity of current density and plating rate across the edge regions of the substrate. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top perspective view of an exemplary electroplating system according to embodiments of the present technology.

FIG. 2 shows a perspective view of a seal assembly according to embodiments of the present technology.

FIG. 2A shows a partial cross-sectional view of the seal assembly of FIG. 2 according to embodiments of the present technology.

FIG. 2B shows a top plan view of the seal assembly of FIG. 2 according to embodiments of the present technology.

FIG. 2C shows a partial cross-sectional view of the seal assembly of FIG. 2 according to embodiments of the present technology.

FIG. 2D shows a partial cross-sectional view of the seal assembly of FIG. 2 according to embodiments of the present technology.

FIG. 3A shows a partial cross-sectional view of a seal assembly according to embodiments of the present technology.

FIG. 3B shows a partial cross-sectional view of a seal assembly of FIG. 3A according to embodiments of the present technology.

FIG. 4A shows a partial cross-sectional view of a seal assembly according to embodiments of the present technology.

FIG. 4B shows a partial cross-sectional view of a seal assembly of FIG. 4A according to embodiments of the present technology.

FIG. 5A shows a partial front plan view of a distal end of a seal assembly according to embodiments of the present technology.

FIG. 5B shows a partial front plan view of a distal end of a seal assembly according to embodiments of the present technology.

FIG. 5C shows a partial front plan view of a distal end of a seal assembly according to embodiments of the present technology.

FIG. 6A shows a partial cross-sectional view of a current path from an anode to a substrate according to embodiments of the present technology.

FIG. 6B shows a partial cross-sectional view of a current path from an anode to a substrate of FIG. 6A according to embodiments of the present technology.

FIG. 7 is a flowchart showing operations of electroplating a substrate according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Electroplating operations may be performed to provide conductive material into vias and other features on a substrate. Electroplating utilizes an electrolyte bath containing ions of the conductive material to electrochemically deposit the conductive material onto the substrate and into the features defined on the substrate. The substrate on which metal is being plated operates as the cathode. An electrical contact, such as a ring or pins, may allow the current to flow through the system. During electroplating, a substrate may be clamped to a head and submerged in the electroplating bath to form the metallization. In systems as described below, the substrate may also be chucked or seated within a seal assembly that may be coupled with the head during processing. The seal assembly may include one or more components that engage the substrate with the electrical contacts and may limit ingression of electrolyte into the head. For example, the seal assembly may include a structural component as well as a flexible material that produces the seal against the substrate. As several of the components of the head may be electrically conductive and in electrical communication, if electrolyte contacts these components during a plating operation, plating or deposition may occur on these components as well.

Common copper damascene substrates (as well as other forms of substrates) may include a notch. To cover the notch, the seal assembly geometry is flatted (i.e., moved radially inward) at regions proximate the notch. However, the extra seal material covers portion of the substrate that would otherwise be active for electroplating. Therefore, current that would have plated onto these areas is crowded into the region near the seal flat causing higher local deposition rates. Conventional solutions to address such issues have included removing material from the seal insert proximate the substrate notch to make the seal insert less restrictive to current flow at this region. In such instances, a thief electrode may be used to draw current from the substrate, with more current being drawn proximate the notch to reduce the current crowding. Additional solutions have included removing the electrical contacts within a region of the notch. However, such solutions may not be effective in all situations, such as when the plating thickness is above a certain threshold.

The present technology overcomes these and other problems by using seal assemblies that incorporate seal inserts with additional material positioned proximate the notch. For example, within an arcuate region of the seal insert, additional material may be added to form a protrusion that projects downward into the plating bath. The protrusion may restrict a size of the current flow path between an anode and the substrate, which may subsequently reduce the current flow and current density proximate the flat region to locally reduce the plating rate. This may result in a more even plating rate about the periphery of the substrate. Some embodiments may additionally remove some or all of the electrical contacts within this region to further improve the plating rate uniformity. In this manner, the present invention may promote fabrication of substrates with more even plating uniformity across the surface of the substrate.

Although the remaining disclosure will routinely identify specific electroplating processes utilizing the disclosed technology, it will be readily understood that the systems and methods are equally applicable to other seals in plating chambers and systems, as well as processes as may occur in the described systems and other semiconductor systems. Accordingly, the technology should not be considered to be so limited as for use with these specific plating processes or systems alone. The disclosure will discuss one possible system that may include electroplating components according to embodiments of the present technology before additional variations and adjustments to this system according to embodiments of the present technology are described.

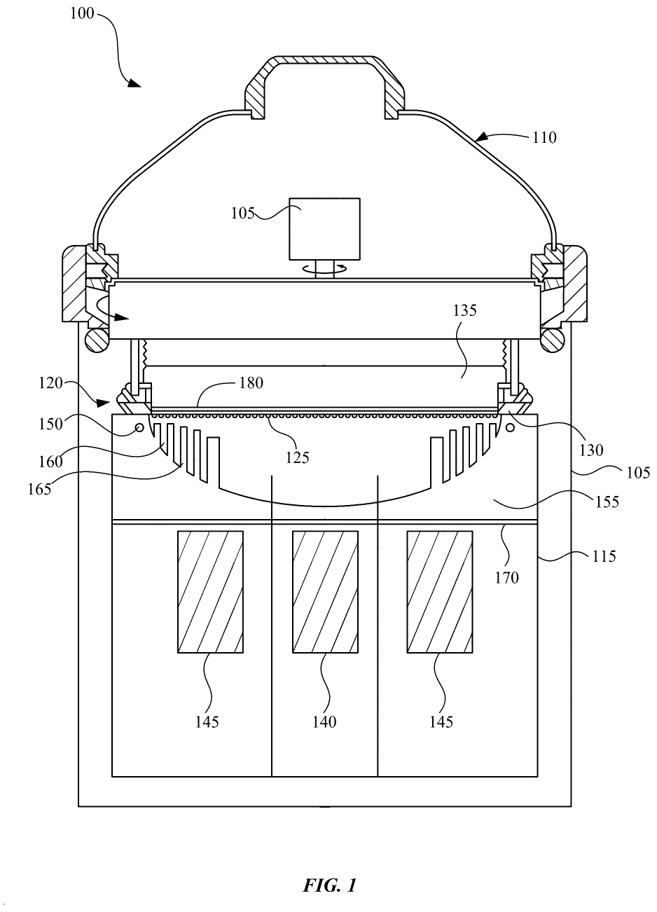

FIG. 1 shows a schematic perspective view of a plating system 100 that can perform plating methods according to embodiments of the present technology. Plating system 100 may be operable to perform both electroplating operations and electroless plating operations. In electroplating operations, the plating system 100 delivers an electric current to a substrate so that ions in an electroplating bath in contact with the substrate may be reduced and plated on the substrate. The plating system 100 illustrates an exemplary plating system, including a substrate carrier head 110 and a vessel 115. During plating operations, a substrate 180 may be clamped to the substrate carrier head 110, inverted, and extended into the vessel 115 to perform a plating operation. The plating system 100 may include a head lifter (not shown), which may be configured to both raise and rotate the system carrier head 110, or otherwise position the system carrier head 110 within the plating system 100, including tilting operations. For example, the head lifter may move the substrate carrier head 110 between a loading position and a plating position (as shown here) in which a portion of the substrate carrier head 110 is disposed in contact with an electrolyte held within the vessel 115. The substrate carrier head 110 and the vessel 115 may be attached to a deck plate or other structure that may be part of a larger system incorporating multiple plating systems 100, and which may share electrolyte and other materials. A rotor 105 may allow the substrate 180 clamped to the substrate carrier head 110 to be rotated within the vessel 115 or outside the vessel 115 in different operations. A seal assembly 120 discussed further below may be connected with the substrate carrier head 110. The seal assembly 120 may include chucked substrate 180 to be processed. The seal assembly 120 may include a number of electrically conductive substrate contacts 125 that may be in contact with a surface of the substrate 180 and that contact the electrolyte when the substrate carrier head 110 is in the plating position. The seal assembly 120 may include a seal insert 130 that may form an outermost surface of the seal assembly 120, as well as a distal end of the seal assembly 120. When the substrate carrier head 110 is in the plating position, a distal end of the seal insert 130 may be in contact with the electrolyte. A backing plate 135 may engage a backside of the seal insert 130 and may help position and retain the substrate 180 in position within the seal assembly 120.

One or more electrodes may be in contact with the liquid electrolyte within the vessel 115. For example, a center electrode 140 may be surrounded by a single annular outer electrode 145, although multiple concentric outer electrodes may be used. Other electrode configurations are possible in various embodiments. The plating system 100 may also include an anode 150 that may be positioned below the seal assembly 120 when the substrate carrier head 110 is in the plating position. For example, the anode 150 may be positioned below the seal insert 130 and radially outward of the substrate 180. The anode 150 may serve as the positive electrode that drives current via gas generation.

The vessel 115 may include an electric field shaping unit 155. The field shaping unit 155 may be made of a di-electric material and may be positioned in (or may form a portion of) the vessel 115 between the electrodes and the substrate 180. In some embodiments, a top surface of the field shaping unit 155 may form a closest portion of the vessel 115 to the seal assembly 120 when the substrate carrier head 110 is in the plating position. The field shaping unit 155 may help control the distribution of electric field delivered to the substrate 180 during plating operations. For example, in some embodiments, the field shaping unit 155 may include a number of electrode compartments 160 separated by partitions 165. Electrolyte may be directed into each compartment 160, past the electrodes 140, 145, and upwardly toward substrate 180. The effect of the field shaping unit 155 on the electrical field produced by the electrodes 140, 145 is as if the electrodes 140, 145 were positioned at the exits of each compartment 160.

A membrane 170 may optionally be included, with anolyte in a lower chamber below the membrane 170 and with catholyte in an upper chamber above the membrane 170. The electrodes 140, 145 may be disposed in the lower chamber, while the field shaping unit 155 may be positioned in the upper chamber. Electric current passes from the electrodes 140, 145 through the electrolyte to a conductive surface on the substrate 180.

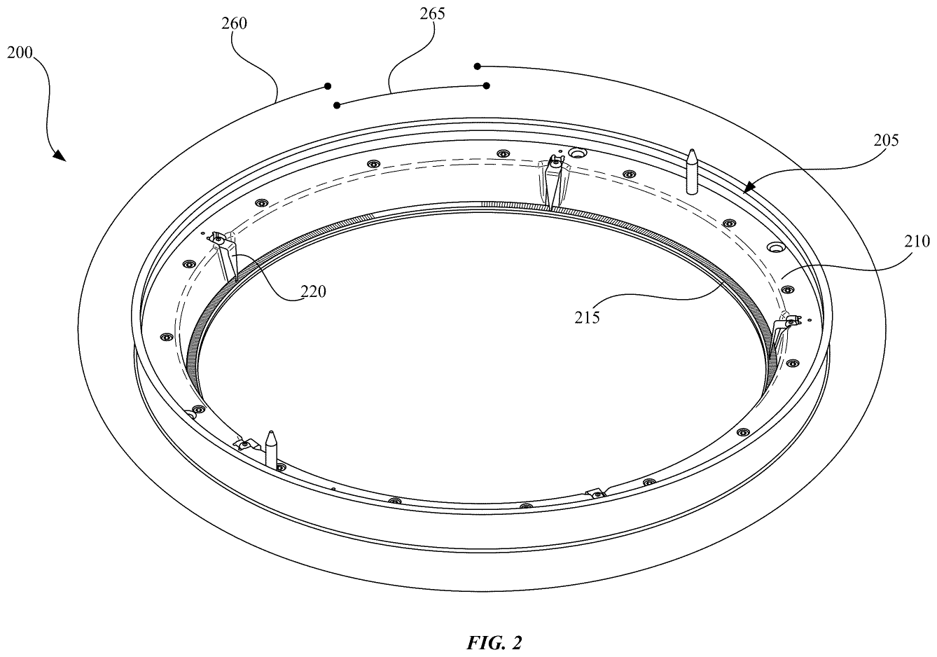

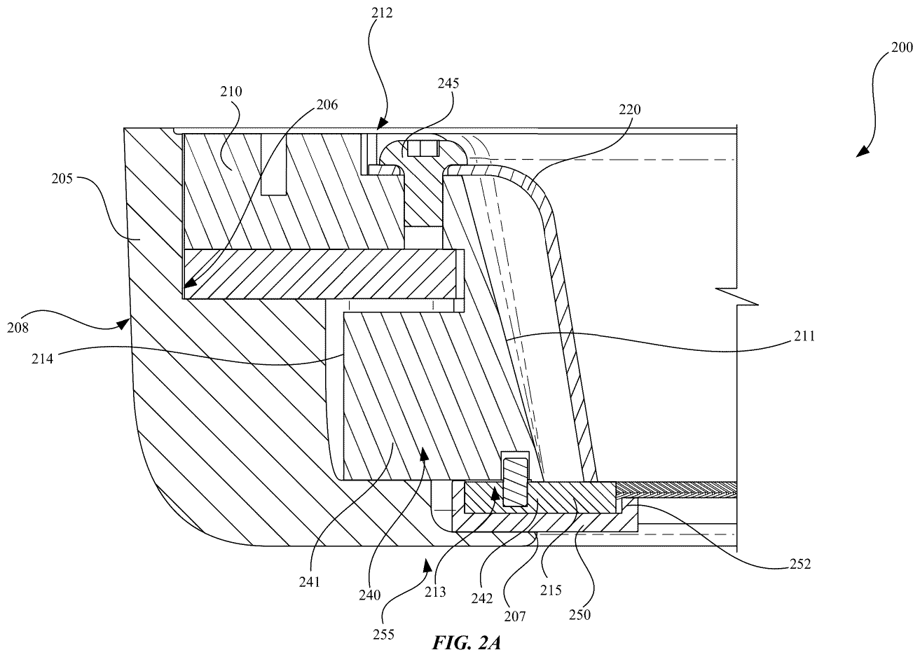

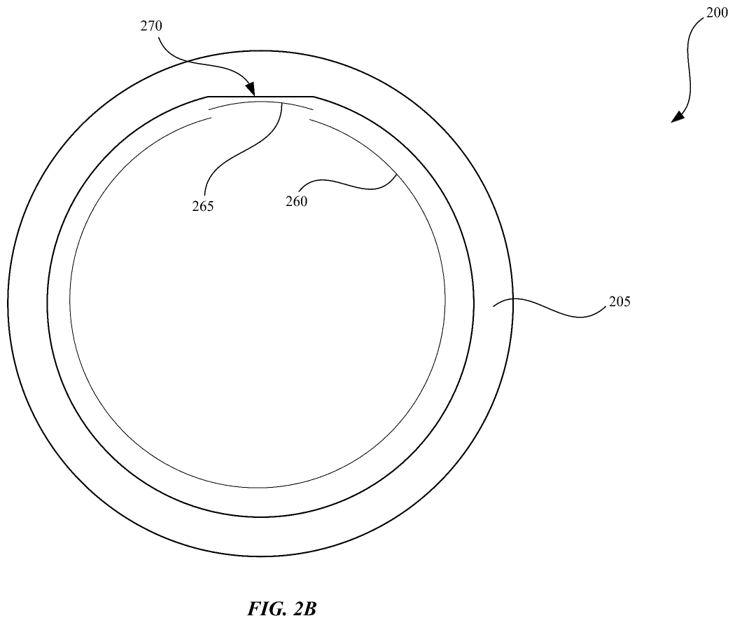

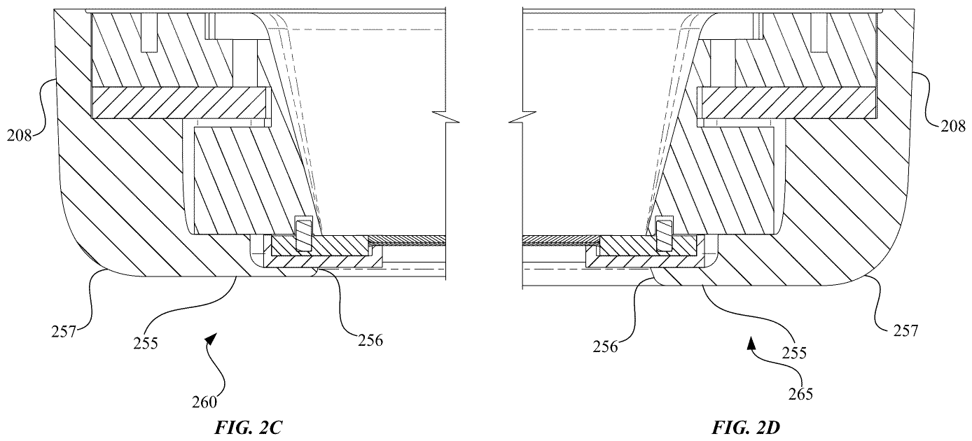

FIG. 2 illustrates a perspective view of a seal assembly 200. The seal assembly 200 may be used in a plating system, such as plating system 100, and may be used as seal assembly 120 in various embodiments. The seal assembly 200 may include a seal insert 205 and a support ring 210. Each of the seal insert 205 and the support ring 210 may be generally annular in shape and may define a central opening. In some embodiments, the support ring 210 may have a smaller outer diameter than the seal insert 205. For example, an inner diameter of the seal insert 205 may be greater than the outer diameter of the support ring 210 such that the support ring 210 is received within the central opening of the seal insert 205. The seal insert 205 may form an outermost surface of the seal assembly 200, with a distal end of the seal insert 205 forming a distal end of the seal assembly 200. In some embodiments, the central opening may be circular or substantially circular in shape. The seal insert 205 and the support ring 210 may be configured to receive a substrate (not shown) within the respective central openings. As best illustrated in FIG. 2A, the seal assembly 200 may include a number of electrically conductive substrate contacts 215. The substrate contacts 215 may be disposed along an inner surface of the support ring 210, such as proximate a substrate-receiving region of the support ring 210. The substrate contacts 215 may be provided at regular (or substantially regular) intervals about the circumference of the support ring 210 to help promote uniform current flow about a substrate received within the seal assembly 200. In some embodiments, the support ring 210 may be and/or may include a busbar that facilitates the flow of electrical current through the substrate contacts 215. The substrate contacts 215 may be shaped in a variety of forms, and may be contact extensions or conductive extensions, which may include looped features in some embodiments to limit any piercing contact with a substrate.

In some embodiments, a width of each of the substrate contacts 215 may be between 0.75 mm and 2 mm, between 0.80 mm and 1.75 mm, or between 0.90 mm and 1.5 mm, although other widths are possible in some embodiments. The substrate contacts 215 may be arranged with gaps between adjacent substrate contacts 215 being smaller than the widths of the substrate contacts 215 themselves. For example, each gap may be no greater than 0.75 mm, no greater than 0.70 mm, no greater than 0.65 mm, no greater than 0.60 mm, no greater than 0.55 mm, no greater than 0.50 mm, no greater than 0.45 mm, no greater than 0.40 mm, no greater than 0.35 mm, no greater than 0.30 mm, no greater than 0.25 mm, no greater than 0.20 mm, no greater than 0.15 mm, no greater than 0.10 mm, no greater than 0.05 mm, or less. In such embodiments, the substrate contacts 215 may collectively cover at least 50% of an inner circumference of the support ring 210, at least 60% of the inner circumference, at least 70% of the inner circumference, at least 75% of the inner circumference, at least 80% of the inner circumference, at least 85% of the inner circumference, at least 90% of the inner circumference, at least 95% of the inner circumference, or more. The seal assembly 200 may include at least 100 substrate contacts, at least 200 substrate contacts, at least 300 substrate contacts, at least 400 substrate contacts, at least 500 substrate contacts, at least 600 substrate contacts, at least 700 substrate contacts, at least 800 substrate contacts, at least 900 substrate contacts, at least 1000 substrate contacts, or more.

In some embodiments, the seal assembly 200 may include a number of lead ins 220 that may help center the substrate within the seal assembly 200. As best illustrated in FIG. 2A, the support ring 210 may include an inner surface 211 that tapers radially inward from a proximal end 212 to a distal end 213 of the support ring 210. The substrate contacts 215 may be coupled with the distal end 213 of the support ring 210 and may protrude into the central opening of the support ring 210. The support ring 210 may include an annular busbar 240. The busbar 240 may receive current through the substrate contacts 215 and may form an electrode with the substrate, which may operate as the cathode on which a reduction reaction and electrical plating may occur. The busbar 240 may be integrally formed with a body of the support ring 210 or may be a separate component disposed within or against the body of the support ring 210 as shown here. For example, the busbar 240 may be disposed against a distal surface of the body of the support ring 210 in some embodiments. The busbar 240 may be an annular component that extends entirely about a circumference of seal assembly 200. As will be discussed in greater detail below, the busbar 240 may be designed to support the seal insert 205 and may form a portion of a path for delivering electrical current to the substrate.

As illustrated, the substrate contacts 215 may be disposed against the second end 213 of the support ring 210 and may be positioned between the second end 213 of the support ring 210 and the busbar 240. A proximal end of each lead in 220 may be coupled with the support ring 210, such as at the proximal end 212. For example, a fastener 245 may be inserted through a slot or aperture formed through the proximal end of the lead in and into a threaded apertured formed within the proximal end 212 of the support ring 210 to secure the lead in 220 to the support ring 210. A portion of each lead in 220 may protrude radially inward beyond and be laterally spaced apart from the inner surface 211 such that a substrate received within the central opening of the support ring 210 must first contact the lead ins 220 and deflect the lead ins 220 radially outward as the substrate is advanced deeper within the support ring 210 and into contact with the substrate contacts 215.

A seal member 250 may be seated atop the busbar 240. In some embodiments, a radially outer portion of the seal member 250 may extend downward along an outer surface of the busbar 240, while a medial portion of the seal member 250 may extend horizontally along a second surface of the busbar 240. An inner edge of the seal member 250 may curl around and cover an inner edge of the busbar 240. In some embodiments, a portion of the inner edge of the seal member 250 may form a seal lip 252 that may protrude beyond the busbar 240 and may be designed to contact a surface of the substrate. The inner edge and the seal lip 252 may be radially inward of the busbar 240 and the inner end of each substrate contact 215. As noted above, the seal member 250 may be designed to contact and form a seal against the substrate without damaging the substrate. For example, the seal member 250, and in particular, seal lip 252, may be formed from a deformable or compressible material. For example, the seal member 250 may be formed from a polymeric member. Additionally, to prevent damage to the substrate, the seal lip 252 may be formed as a rounded or otherwise dull protrusion to limit scratching or other damage of the substrate. The seal member 250 may be configured to support a substrate between the seal member 250 and the plurality of substrate contacts 215. In compression or deformation, the seal member 250 may form a substantially, essentially, or otherwise complete seal between the seal member 250 and a supported substrate, which may ensure electrolyte fluid may not flow within the seal assembly 200, or interact with the substrate contacts 215, the busbar 240, and/or other internal components of the head assembly on which seal assembly 200 may reside.

The seal insert 205 may form an enclosure about portions of the busbar 240 and support ring 210 that may be exposed to an electroplating solution. The seal insert 205 may be coupled with the busbar 240 and/or support ring 210 in a number of ways and may be bolted or otherwise mechanically coupled with the busbar 240 and/or support ring 210 various embodiments. For example, the coupling may include adhesive or other irreversible couplings, although in some embodiments the coupling may be a reversible coupling, such as with screws, bolts, or other mechanical fasteners that enable the busbar 240 and/or support ring 210 to be removed from seal insert 205. The seal insert 205 may be an annular component extending about a central axis through the seal assembly 200. The seal insert 205 may be characterized by an inner annular radius at an inner sidewall 206 and an outer annular radius at an outer sidewall 208. The seal insert 205 may extend radially outward of the busbar 240 and/or support ring 210. For example, the outer sidewall 208 may extend radially outward of the outermost surfaces of the busbar 240 and/or support ring 210. The seal insert 205 may be seated against a portion of the seal member 250 and may provide a more rigid structural support for the seal member 250, which may nest or otherwise be received within a portion of the seal insert 205. For example, an inner portion of the seal insert 205 may include a downward-protruding lip 207 that may extend toward and may contact a surface of the seal member 250 to compress and retain the seal member 250 between the seal insert 250 and the busbar 240.

A distal end 255 of the seal insert 205 may form a distal end of the seal assembly 200 and may be placed into contact with the electrolyte during plating operations. The distal end 255 may be divided into a first arcuate region (represented by reference line 260) and a second arcuate region (represented by reference line 265). The first arcuate region 260 may form at least 320 degrees of a circumference of the seal insert 205, at least 330 degrees of the circumference, at least 340 degrees, or more. In some embodiments, the first arcuate region 260 may form no greater than 350 degrees of the circumference, no greater than 340 degrees of the circumference, or no greater than 330 degrees of the circumference. For example, the first arcuate region 260 may form between about 320 degrees and 350 degrees of the circumference. The second arcuate region 265 may form a remaining portion of the circumference of the seal insert 205. For example, the second arcuate region 265 may form no greater than 40 degrees of the circumference, no greater than 35 degrees of the circumference, no greater than 30 degrees of the circumference, no greater than 25 degrees of the circumference, no greater than 20 degrees of the circumference, no greater than 15 degrees, or no greater than 10 degrees of the circumference. The second arcuate region 265 may form at least 5 degrees of the circumference, at least 10 degrees of the circumference, at least 15 degrees of the circumference, at least 20 degrees of the circumference, at least 25 degrees of the circumference, at least 30 degrees of the circumference, at least 35 degrees of the circumference, or more. For example, the second arcuate region 265 may form between 5 degrees and 40 degrees of the circumference of the seal insert 205.

The second arcuate region 265 may be positioned in angular alignment with a flatted region 270 (as shown in FIG. 2B) of the seal assembly 200, with the second arcuate region 265 being centered relative to the flatted region 270. The flatted region 270 may include flatted (e.g., non-arcuate) portions of the seal insert 205 and/or the seal member 250 that are closer to the center of the seal assembly 200 than the rest of the arcuate portion of the circumference and that are designed to be aligned with and seal against a flatted or notched edge of a substrate. In some embodiments, an angular size (e.g., number of degrees) of the second arcuate region 265 may match an angular size of the flatted region(s), while in other embodiments, an angular size of the second arcuate region 265 may be slightly smaller or larger than the angular size of the flatted region(s). For example, the angular size of the second arcuate region 265 may be within (e.g., larger or smaller) 20 degrees of the angular size of the flatted region(s), within 15 degrees of the angular size of the flatted region(s), within 10 degrees of the of the angular size of the flatted region(s), within 5 degrees of the angular size of the flatted region(s), or less.

Within the first arcuate region 260, the distal end 255 of the seal insert 205 may have a first protrusion shape and/or protrusion distance that remains uniform along the entire circumferential length of the first arcuate region 260. For example, as illustrated in FIG. 2C, the distal end 255 of the seal insert 205 in the first arcuate region 260 is generally planar from an inner edge 256 of the distal end 255 to a curved transition 257 that forms an initial portion of a transition from the distal end 255 to the outer sidewall 208 in a direction of a proximal end of the seal insert 205. Within the second arcuate region 265, the distal end 255 of the seal insert 205 may have a second protrusion shape and/or protrusion distance that protrudes beyond the first protrusion shape and/or protrusion distance. The second protrusion shape and/or distance may extend along all or a portion of the circumferential length of the second arcuate region 265. The second protrusion shape and/or distance may extend along all or a portion of the radial distance between the inner edge 256 to the curved transition 257. As illustrated in FIG. 2D, the distal end 255 of the seal insert 205 in the second arcuate region 265 is also generally planar from the inner edge 256 to the curved transition 257, however the thickness of the seal insert 205 has been increased in this region of the seal insert 205 to increase the protrusion distance relative to that in the first arcuate region 260.

In some embodiments, a maximum protrusion distance (e.g., a maximum thickness or downward protrusion distance of the distal end 255) within the second arcuate region 265 may be greater than a maximum protrusion distance within the first arcuate region by at least 25%, at least 50%, at least 75%, at least 100%, at least 125%, at least 150%, or more. In some embodiments, this may result in a maximum protrusion distance within the second arcuate region 265 being at least 0.5 mm greater than that within the first arcuate region 260, at least 0.75 mm greater, at least 1 mm greater, at least 1.25 mm greater, at least 1.5 mm greater, at least 1.75 mm greater, at least 2 mm greater, or more. The increased maximum protrusion distance may help reduce current crowding and plating rate within the second arcuate region 265 as will be discussed in greater detail below.

In some embodiments, the seal assembly 200 may be devoid of the substrate contacts 215 that are in angular alignment with the second arcuate region 265. This may further assist in reducing the current density and plating rate within the second arcuate region 265. As noted above, the entire portion of the seal assembly 200 in angular alignment with the second arcuate region 265 may be devoid of the substrate contacts 215. In other embodiments, a smaller region or greater region of the seal assembly 200 may be devoid of substrate contacts 215. For example, an angular size of the second arcuate region 265 may be slightly smaller or larger than the angular size of the contactless region. For example, the angular size of the second arcuate region 265 may be within (e.g., larger or smaller) 20 degrees of the angular size of the contactless region, within 15 degrees of the angular size of the contactless region, within 10 degrees of the of the angular size of the contactless region, within 5 degrees of the angular size of the contactless region, or less. In some embodiments, at least 10 degrees of the seal assembly 200 in angular alignment with the second arcuate region 265 may be devoid of the substrate contacts 215.

FIGS. 3A and 3B illustrate cross-sectional views of a seal insert 300 for a seal assembly, such as seal assemblies 120 and/or 200. The seal insert 300 may be similar to seal inserts 130 and 205 and may include any of the features described in relation thereto. The seal insert 300 may include a distal end 305. Within a first arcuate region, the distal end 305 may have a first protrusion shape and/or protrusion distance as shown in FIG. 3A. For example, the distal end 305 of the seal insert 300 in the first arcuate region is generally planar from an inner edge 310 to a curved transition 315. Within a second arcuate region, the distal end 305 of the seal insert 300 may have a second protrusion shape and/or protrusion distance as shown in FIG. 3B. For example, the distal end 305 of the seal insert 300 in the second arcuate region is also generally planar from the inner edge 310 to the curved transition 315, however the thickness of the seal insert 300 has been increased in this region of the seal insert 300 to increase the protrusion distance relative to that in the first arcuate region. Additionally, a transition 320 from the inner edge 310 to the maximum thickness of the distal end 305 is angled and/or curved, which may move the beginning of the maximum thickness region radially outward, which may impact the current density and plating rate as will be discussed in greater detail below. The angle and/or curvature of the transition 320 may be selected to move the beginning of the maximum thickness region radially outward by a predetermined distance. This distance may be between 0.1 mm and 1.5 mm, between 0.2 mm and 1.4 mm, between 0.3 mm and 1.3 mm, between 0.4 mm and 1.2 mm, or between 0.5 mm and 1 mm.

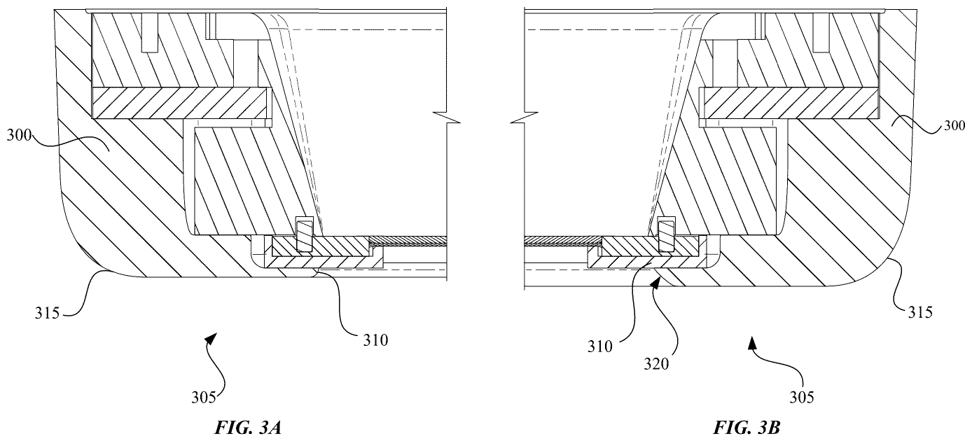

FIGS. 4A and 4B illustrate cross-sectional views of a seal insert 400 for a seal assembly, such as seal assemblies 120 and/or 200. The seal insert 400 may be similar to seal inserts 130, 205, and 300 and may include any of the features described in relation thereto. The seal insert 400 may include a distal end 405. Within a first arcuate region, the distal end 405 may have a first protrusion shape and/or protrusion distance as shown in FIG. 4A. For example, the distal end 405 of the seal insert 400 in the first arcuate region is generally planar from an inner edge 410 to a curved transition 415. Within a second arcuate region, the distal end 405 of the seal insert 400 may have a second protrusion shape and/or protrusion distance as shown in FIG. 4B. For example, the distal end 405 of the seal insert 400 in the second arcuate region may protrude to the second protrusion distance within a medial region 425 that is disposed between the inner edge 410 the curved transition 415. As illustrated, a thickness of the distal end 405 tapers from the inner edge 410 to the second protrusion distance, which transitions to the curved transition 415. The transition from the inner edge 410 to the second protrusion distance may be at a constant rate as illustrated, or at a variable rate (e.g., with a curvature). In other embodiments, the transition may be stepped. In some embodiments, the transition point may be radially outward of the inner edge 410 to the second protrusion distance and may fall within the medial region 425. While shown with the second protrusion distance extending to the curved transition 415, it will be appreciated that the second protrusion distance may terminate radially inward of the curved transition 415.

It will be appreciated that the shapes and sizes of the distal ends of seal inserts are merely provided as examples and that numerous variations are possible. Additionally, various features of the disclosed seal inserts may be combined and/or omitted from the seal inserts in various embodiments.

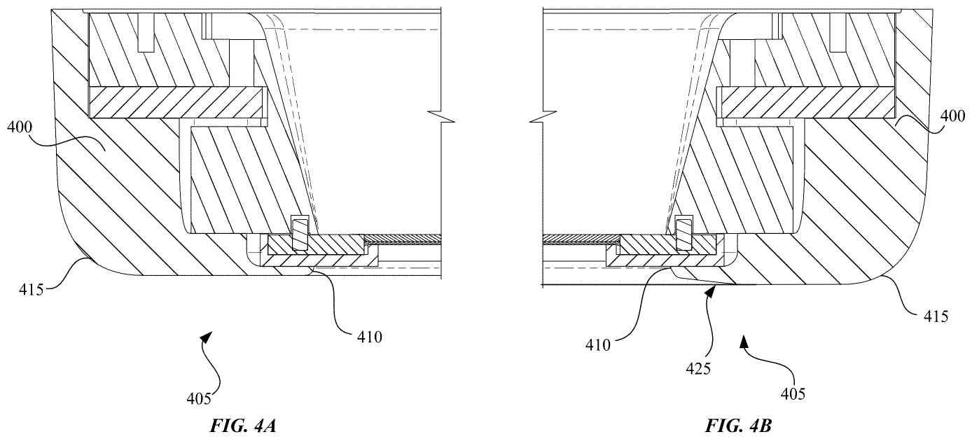

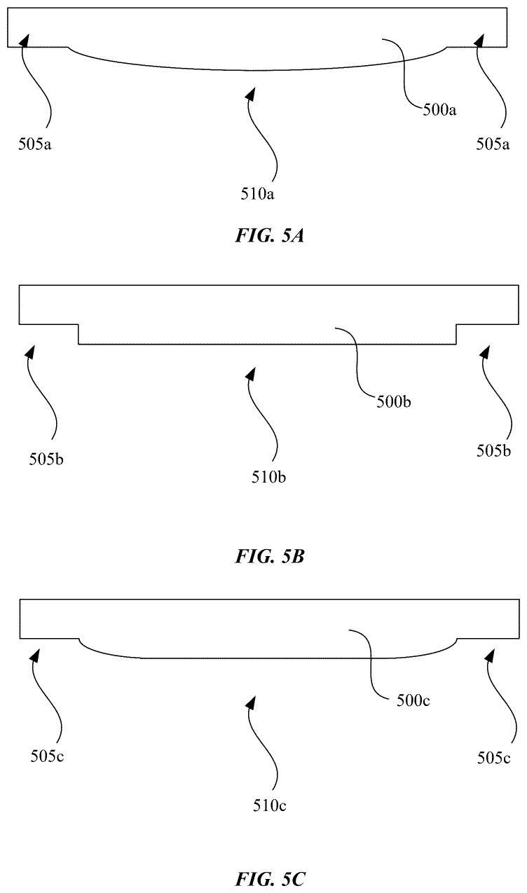

FIGS. 5A-5C illustrate transitions between first arcuate regions 505 and second arcuate regions 510 of the distal ends of seal inserts 500. In some embodiments, within the second arcuate region 510, the distal end of the seal insert 500 tapers from a first protrusion distance at a first end of second arcuate region 510 to the second protrusion distance at a center of the second arcuate region 510 and back to the first protrusion distance at a second end of the second arcuate region 510. The taper of the seal insert 500a may be continuous (at a constant or variable rate) from the center of the second arcuate region 510a to each of the first end and the second end of the second arcuate region 510a (e.g., only the center reaches the full second protrusion distance) as shown in FIG. 5A. The taper (at a constant or variable rate) may extend only a portion of the angular distance from center of the second arcuate region 510b to each end of the second arcuate region 510b such that a medial portion of the distal end of the seal insert 500b is at a constant protrusion distance along a portion of the second arcuate region 510b that extends through a center of the second arcuate region 510b as shown in FIG. 5B. In other embodiments, each boundary between the first arcuate region 510c of seal insert 500c and the second arcuate region 510c may include a stepped transition from the first protrusion distance to the second protrusion distance such that the entire second arcuate region 510c has the second protrusion distance as shown in FIG. 5C. In some embodiments, various combinations of transitions (e.g., a mix of stepped and tapered/curved transitions) may be utilized.

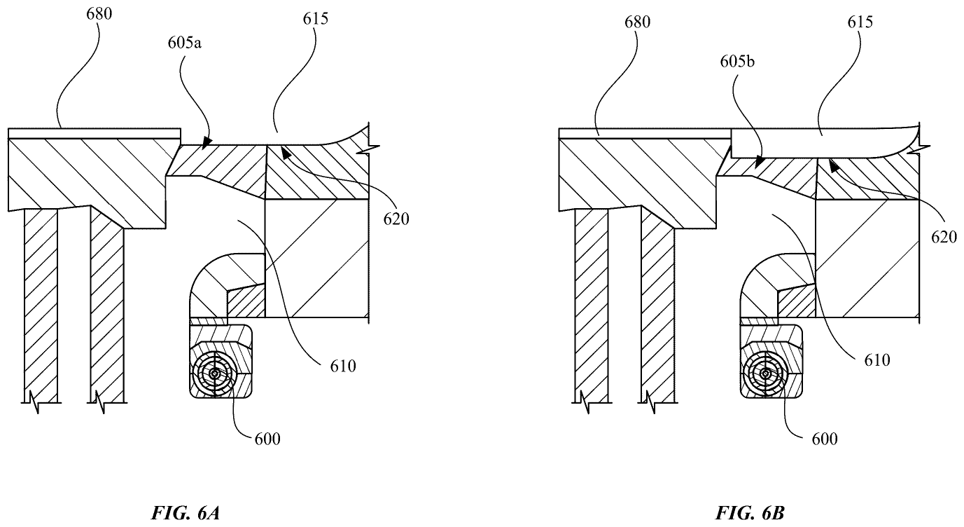

FIGS. 6A and 6B illustrate flow paths of current from an anode 600 (such as anode 150) to a substrate 680 (such as substrate 180) and inner region of an electroplating vessel 610 (such as vessel 115). A portion of each flow path is defined by the distal end 620 of an annular seal insert 615 (which may be similar to seal inserts (130, 205, 300, 400, and 500) and an upper surface of the vessel 610. In some embodiments, the upper surface of the vessel 610 may be formed from a field shaping unit (such as field shaping unit 155). The portion of the flow path defined by the distal end 620 of the annular seal insert 615 and the upper surface of the vessel 610 may form a choke point 605 (e.g., thinnest or otherwise smallest cross-sectional area) of the flow path and may restrict current flow from the anode 600 to the substrate 680. FIG. 6A illustrates a cross-section of the flow path taken through a first arcuate region (similar to those described above), while FIG. 6B illustrates a cross-section of the flow path taken through a second arcuate region (similar to those described above). Due to the increased maximum protrusion distance a minimum depth/thickness of the choke point 605b may be reduced within the second arcuate region as compared to the choke point 605a in the first arcuate region. For example, the minimum depth of the fluid path may be reduced by at least 50% within the second arcuate region as compared to the first arcuate region, by at least 60%, by at least 70%, by at least 80%, by at least 90%, or more. This may result in the minimum depth of the fluid path being reduced by at least 0.5 mm within the second arcuate region as compared to the first arcuate region, by at least 0.75 mm, by at least 1 mm, by at least 1.25 mm, by at least 1.5 mm, by at least 1.75 mm, by at least 2 mm, by at least 2.25 mm, by at least 2.5 mm, or more. For example, in some embodiments the minimum depth at the choke point 605a may be between 2.5 mm and 5 mm, while the minimum depth at the choke point 605b may be between 0.5 mm and 2.5 mm.

The reduced depth and/or surface area at the choke point 605b within the second arcuate region may restrict current flow from the anode 600 to the substrate 680 to a greater degree than the choke point 605a within the first arcuate region, which may enable the current density within the second arcuate region (e.g., near the flat or notch of the substrate 680) to be reduced to combat current crowding issues that otherwise occur at the flat or notch of the substrate 680. This may, in turn, reduce the plating rate in this area, which may result in more uniform plating about the peripheral edge of the substrate 680.

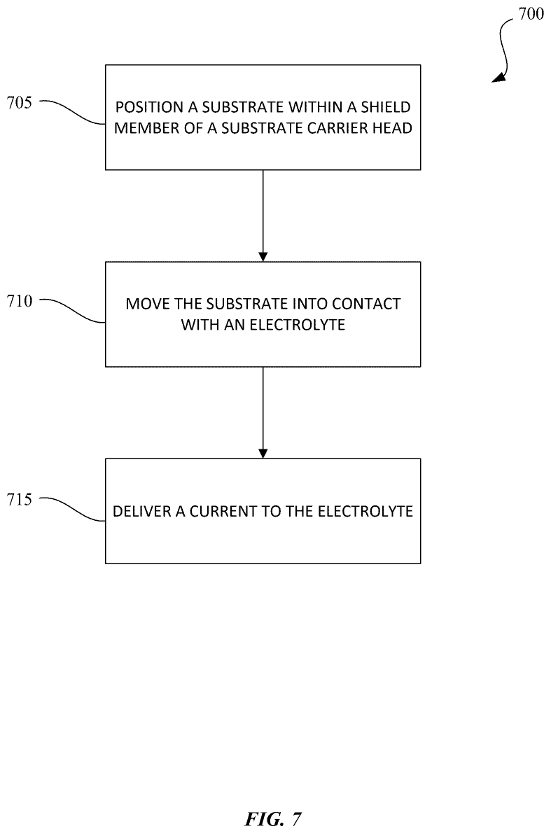

FIG. 7 shows operations of an exemplary method 700 of electroplating a substrate according to some embodiments of the present technology. The method may be performed in a variety of plating chambers, including plating system 100 described above, which may include seal inserts having distal ends according to embodiments of the present technology, such as seal inserts 130, 205, 300, 400, 500, and 615). Method 700 may include a number of optional operations, which may or may not be specifically associated with some embodiments of methods according to the present technology.

Method 700 may include a processing method that may include operations for plating a wafer or other substrate. The method may include optional operations prior to initiation of method 700, or the method may include additional operations. For example, method 700 may include operations performed in different orders than illustrated. Method 700 may include positioning a substrate within an annular seal insert of a substrate carrier head such that a flat region of a peripheral edge is aligned with a second arcuate region of a distal end of the annular seal insert at operation 705. For example, the flat region may be centered with respect to the second arcuate region in some embodiments. A non-flatted region of the substrate may be aligned with a first arcuate region of the seal insert. The first arcuate region may have a first protrusion distance that is uniform along a length of the first arcuate region, while the second arcuate region may include a second protrusion distance that is greater than the first protrusion distance.

At operation 710, the substrate carrier head may be moved into a plating position in which the substrate and the distal end of the annular seal insert are in contact within an electrolyte held within an electroplating vessel. At operation 715, a current may be delivered to the electrolyte and substrate from an anode via a flow path defined between an upper surface of the electroplating vessel and the distal end of the annular seal insert. The cross-sectional area of the flow path may control the magnitude of current delivered to the substrate. The second protrusion distance within the second arcuate region may reduce the cross-sectional area of the flow path further than in the first arcuate region, which may more greatly restrict the current to the flat region than to the arcuate region of the substrate. This reduced current may help counteract the occurrence of current crowding within the flat region to improve the uniformity of plating rate across the peripheral edge of the substrate.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the mesh” includes reference to one or more meshes and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. An electroplating system, comprising:
a vessel configured to hold an electrolyte;
a substrate carrier head comprising a seal assembly, wherein:
the seal assembly comprises an annular seal insert that forms an outermost surface of the seal assembly;
a distal end of the annular seal insert comprises a first arcuate region and a second arcuate region;
the first arcuate region forms at least 320 degrees of a circumference of the annular seal insert;
the second arcuate region forms no greater than 40 degrees of the circumference of the annular seal insert;
the first arcuate region comprises a first protrusion distance that is uniform along a length of the first arcuate region;
the second arcuate region comprises a second protrusion distance that is greater than the first protrusion distance; and
the substrate carrier head is moveable between a loading position and a plating position in which the distal end of the annular seal insert is in contact with the electrolyte; and
an anode disposed below the seal assembly when the substrate carrier head is in the plating position.

2. The electroplating system of claim 1, wherein:
the vessel comprises a field shaping unit; and
a top surface of the field shaping unit forms a closest portion of the vessel to the seal assembly when the substrate carrier head is in the plating position.

3. The electroplating system of claim 1, wherein:
within the second arcuate region, the distal end of the annular seal insert tapers from the first protrusion distance at a first end of second arcuate region to the second protrusion distance at a center of the second arcuate region and to the first protrusion distance at a second end of the second arcuate region.

4. The electroplating system of claim 3, wherein:
the distal end of the annular seal insert tapers continuously from the center of the second arcuate region to each of the first end and the second end of the second arcuate region.

5. The electroplating system of claim 1, wherein:
a flow path from the anode to an inner region of the vessel disposed radially inward of the annular seal insert is defined by the distal end of the annular seal insert and an upper surface of the vessel.

6. The electroplating system of claim 5, wherein:
a minimum depth of the flow path is reduced by at least 1.5 mm at an angular location of the second protrusion distance relative to the minimum depth of the flow path at an angular location of the first protrusion distance.

7. The electroplating system of claim 5, wherein:
a minimum depth of the flow path is reduced by at least 50% at an angular location of the second protrusion distance relative to the minimum depth of the flow path at an angular location of the first protrusion distance.

8. The electroplating system of claim 1, wherein:
the seal assembly comprises a plurality of electrically conductive substrate contacts disposed within a central opening of the seal assembly; and
at least 10 degrees of the seal assembly in angular alignment with the second arcuate region is devoid of the plurality of electrically conductive substrate contacts.

9. The electroplating system of claim 8, wherein:
an entirety of the seal assembly in angular alignment with the second arcuate region is devoid of the plurality of electrically conductive substrate contacts.

10. A seal assembly for an electroplating system, comprising:
an annular support ring having a proximal end and a distal end;
an annular busbar coupled with the distal end of the annular support ring;
a plurality of electrically conductive substrate contacts disposed between the annular busbar and the annular support ring, the plurality of electrically conductive substrate contacts extending into a central opening of the annular support ring, the plurality of electrically conductive substrate contacts being disposed about a circumference of the central opening;
a seal member disposed against an outer surface of the annular busbar; and
an annular seal insert disposed against an outer surface of the seal member, a distal end of the annular seal insert forming a distal end of the seal assembly, wherein:
the distal end of the annular seal insert comprises a first arcuate region and a second arcuate region;
the first arcuate region forms at least 320 degrees of a circumference of the annular seal insert;
the second arcuate region forms no greater than 40 degrees of the circumference of the annular seal insert;
the first arcuate region comprises a first protrusion distance that is uniform along a length of the first arcuate region; and
the second arcuate region comprises a second protrusion distance that is greater than the first protrusion distance.

11. The seal assembly for an electroplating system of claim 10, wherein:
at least 10 degrees of the seal assembly in angular alignment with the second arcuate region is devoid of the plurality of electrically conductive substrate contacts.

12. The seal assembly for an electroplating system of claim 10, wherein:
within the second arcuate region, the distal end of the annular seal insert tapers from the first protrusion distance at a first end of second arcuate region to the second protrusion distance at a center of the second arcuate region and to the first protrusion distance at a second end of the second arcuate region.

13. The seal assembly for an electroplating system of claim 10, wherein:
each boundary between the first arcuate region and the second arcuate region comprises a stepped transition from the first protrusion distance to the second protrusion distance.

14. The seal assembly for an electroplating system of claim 10, wherein:
the annular seal insert comprises a curved transition from the distal end to an outer surface of the annular seal insert; and
the distal end is planar from an inner edge of the annular seal insert to the curved transition.

15. The seal assembly for an electroplating system of claim 10, wherein:
the annular seal insert comprises a curved transition from the distal end to an outer surface of the annular seal insert; and
the distal end of the annular seal insert protrudes to the second protrusion distance within a medial region that is disposed between an inner edge of the annular seal insert and the curved transition.

16. A method of electroplating a substrate, comprising:
positioning a substrate within an annular seal insert of a substrate carrier head such that a flat region of a peripheral edge is aligned with a second arcuate region of a distal end of the annular seal insert, wherein:
the distal end of the annular seal insert comprises a first arcuate region and the second arcuate region;
the first arcuate region forms at least 320 degrees of a circumference of the annular seal insert;
the second arcuate region forms no greater than 40 degrees of the circumference of the annular seal insert;
the first arcuate region comprises a first protrusion distance that is uniform along a length of the first arcuate region; and
the second arcuate region comprises a second protrusion distance that is greater than the first protrusion distance;
moving the substrate carrier head into a plating position in which the substrate and the distal end of the annular seal insert are in contact within an electrolyte held within an electroplating vessel; and
delivering a current to the electrolyte from an anode via a flow path defined between an upper surface of the electroplating vessel and the distal end of the annular seal insert.

17. The method of electroplating a substrate of claim 16, wherein:
an angular size of the second arcuate region matches an angular size of the flat region.

18. The method of electroplating a substrate of claim 16, wherein:
an angular size of the second arcuate region is smaller than an angular size of the flat region.

19. The method of electroplating a substrate of claim 16, wherein:
an angular size of the second arcuate region is greater than an angular size of the flat region.

20. The method of electroplating a substrate of claim 16, wherein:
the substrate carrier head comprises a plurality of electrically conductive substrate contacts disposed within a central opening of the substrate carrier head; and
at least 10 degrees of substrate carrier head in angular alignment with the second arcuate region is devoid of the plurality of electrically conductive substrate contacts.
